(19) United States
(12) Patent Application Publication
(10) Pub. No.: US 2010/0060193 A1
(43) Pub. Date: Mar. 11, 2010

(54) METHOD AND CIRCUIT ARRANGEMENT FOR INCREASING THE DIELECTRIC STRENGTH OF METAL OXIDE TRANSISTORS AT LOW TEMPERATURES

(75) Inventor: Joachim Muehlschlegel, Groebenzell (DE)

Correspondence Address: Viering, Jentschura & Partner - OSR, 3770 Highland Ave., Suite 203, Manhattan Beach, CA, 90266, US

(73) Assignee: OSRAM GESELLSCHAFT MIT BESCHRAENKTER HAFTUNG, Muenchen (DE)

(21) Appl. No.: 12/556,725

(22) Filed: Sep. 10, 2009

(30) Foreign Application Priority Data
Sep. 11, 2008 (DE) 10 2008 046 734.0

(51) Int. Cl. H05B 41/36; H03H 11/00

(52) U.S. Cl. 315/291; 327/581

(57) ABSTRACT

A method and circuit arrangement for increasing the dielectric strength of at least one metal oxide transistor at low temperatures is described. Various embodiments include heating the metal oxide transistor prior to the application of a voltage in the vicinity of a breakdown voltage of the metal oxide transistor.

### RELATED APPLICATIONS

The present application claims priority to German Patent Application No. 10 2008 046 734.0 filed Sep. 11, 2008, the disclosure of which is incorporated herein by reference in its entirety.

### FIELD

The invention relates to a method for increasing the temperature-independent dielectric strength of electronic circuit arrangements having metal oxide transistors and to a circuit arrangement having at least one metal oxide transistor and an increased temperature-independent dielectric strength.

### BACKGROUND

FIG. 1 is a diagram of the normalized breakdown voltage of a conventional metal oxide transistor, also abbreviated to MOSFET, plotted against the chip temperature. It can clearly be seen that as the temperature of the metal oxide transistor decreases, the breakdown voltage of the metal oxide transistor likewise decreases considerably. This raises the problem that the dielectric strength of an entire circuit arrangement having such a metal oxide transistor likewise decreases at low temperatures. In order to avoid this problem, metal oxide transistors having a higher reverse voltage have been used hitherto. However, these transistors are considerably more expensive, and have disadvantages such as a higher channel resistance (RDS_{On}). The problem is manifested particularly seriously if metal oxide transistors that exceed a technologically dictated voltage level have to be selected on account of the boundary conditions. If such a level is exceeded, use is made of other semiconductor chips in the transistor, which are significantly more costly on account of a different fabrication technology. In such a case, it is necessary to reckon with considerable extra costs for a metal oxide transistor having a higher reverse voltage. As an alternative, a narrower temperature range can be specified for the circuit arrangement. However, this is often not possible on account of the application.

### SUMMARY

The present disclosure describes several embodiments of the present invention.

Embodiments include methods for increasing the dielectric strength of an electronic circuit arrangement at low temperatures, wherein the circuit arrangement has at least one metal oxide transistor, so that the selection of a metal oxide transistor having a higher reverse voltage is no longer necessary.

Embodiments also include a circuit arrangement having an increased dielectric strength at low temperatures, wherein the circuit arrangement has at least one metal oxide transistor without the metal oxide transistor having a higher reverse voltage.

In one embodiment, a method for increasing the dielectric strength of an electronic circuit arrangement at low temperatures, the circuit arrangement has at least one metal oxide transistor, and, prior to the application of a voltage in the vicinity of the breakdown voltage of the metal oxide transistor, the metal oxide transistor is heated to a predetermined temperature by suitable measures.

In another embodiment, the heating of the metal oxide transistor is achieved in this case by a high current through the metal oxide transistor. In another embodiment, the heating of the metal oxide transistor is realized by an increase in the switching losses of the metal oxide transistor. In another embodiment, the heating of the metal oxide transistor is realized by momentary linear operation of the metal oxide transistor. These embodiments ensure rapid and reliable heating of the metal oxide transistor.

Embodiments include heating in either a time-controlled or temperature-controlled fashion. The time-controlled embodiments include heating the metal oxide transistor for a predetermined time. It affords the advantage of a cost-effective implementation. The temperature-controlled embodiments include measuring the temperature of the circuit arrangement or the metal oxide transistor and heating the metal oxide transistor to a predetermined temperature (e.g. 25° C.). It affords the advantage of good temperature regulation of the metal oxide transistor.

In some embodiments, the heating is realized only at low temperatures of the circuit arrangement or of the metal oxide transistor. This prevents overheating of the metal oxide transistor at higher temperatures of the circuit arrangement or of the metal oxide transistor.

Some embodiments provide a circuit arrangement having an increased dielectric strength at low temperatures, wherein the circuit arrangement has at least one metal oxide transistor, and the circuit arrangement has means for heating the metal oxide transistor before the circuit arrangement applies to the metal oxide transistor a voltage in the vicinity of the reverse voltage of the metal oxide transistor.

In one embodiment, the heating of the metal oxide transistor is achieved in this case by a high current through the metal oxide transistor. In another embodiment, the heating of the metal oxide transistor is realized by an increase in the switching losses of the metal oxide transistor. In another embodiment, the heating of the metal oxide transistor is realized by momentary linear operation of the metal oxide transistor. These embodiments ensure rapid and reliable heating of the metal oxide transistor. They can be combined as desired depending on the application and requirements.

In some embodiments, the circuit arrangement preferably heats the metal oxide transistor only at low temperatures of the circuit arrangement or of the metal oxide transistor. This prevents overheating of the metal oxide transistor at higher temperatures of the circuit arrangement or of the metal oxide transistor.

Embodiments include heating in either a time-controlled or temperature-controlled fashion. The time-controlled embodiment affords the advantage of a cost-effective implementation. The temperature-controlled embodiment affords the advantage of precise temperature regulation of the metal oxide transistor. In some embodiments, the circuit arrangement preferably measures the temperature of the metal oxide transistor. In some embodiments, the temperature of the metal oxide transistor is preferably measured by way of the channel resistance thereof. This affords the advantage of a simple and cost-effective implementation of the temperature measurement.

In some embodiments, the circuit arrangement is preferably designed to operate at least one gas discharge lamp, in which case it generates an intermediate circuit voltage for application to the metal oxide transistor, and heats the metal oxide transistor shortly before the start of the gas discharge lamp or upon the start of the gas discharge lamp. In this embodiment, “shortly before the start” means that the circuit arrangement utilizes the time before the lamp start, in which time it builds up the ignition voltage, for heating the metal oxide transistor. In some embodiments, the intermediate circuit voltage is advantageously reduced during the heating phase, and the heating phase has a length of between 1 s and 120 s. In some embodiments, the metal oxide transistor is protected by the reduction of the intermediate circuit voltage, and the length of the heating phase guarantees effective heating of the transistor. The reduction of the intermediate circuit voltage is preferably realized by a DC voltage converter which has an adjustable output voltage, and the output voltage of which is the intermediate circuit voltage. Since a DC voltage converter is in many cases also used for other reasons, it is advantageous for this DC voltage converter that is already present to be made adjustable in terms of its output voltage with little outlay, in order to be able to adjust the intermediate circuit voltage.

Further advantageous developments and configurations of the method according to the embodiments and of the circuit arrangement according to the embodiments emerge from further dependent claims and from the following description.

### BRIEF DESCRIPTION OF THE DRAWING

Further advantages, features and details of the invention will become apparent on the basis of the following description of exemplary embodiments and with reference to the drawing, in which:

FIG. 1 is a diagram of the normalized breakdown voltage of a metal oxide transistor according to the prior art, plotted against the chip temperature.

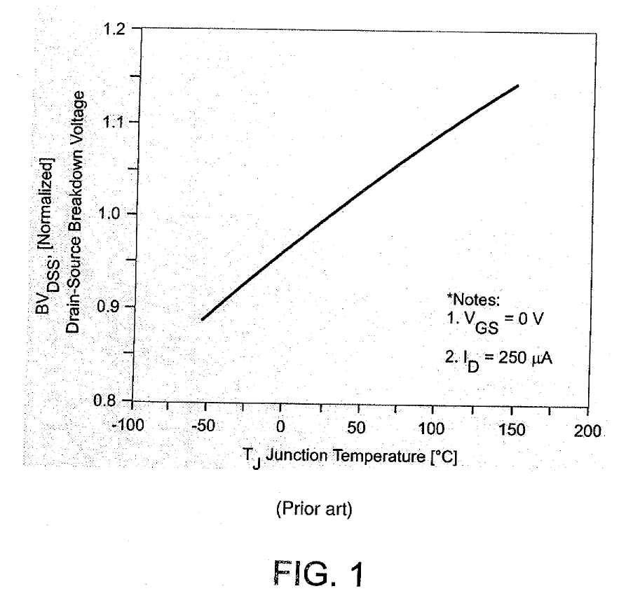

### DETAILED DESCRIPTION

By means of an intelligent control of the circuit arrangement having a metal oxide transistor, it is possible to use a metal oxide transistor which does not have an increased reverse voltage. According to the invention, prior to application of a voltage to the metal oxide transistor which is in the region of the reverse voltage of the metal oxide transistor, the latter is heated to a temperature at which it can reliably block the voltage to be applied. The temperature dependence of the reverse voltage of metal oxide transistors is therefore utilized.

In one preferred embodiment, the metal oxide transistor is used as a switching transistor in the inverter of an electronic operating device for gas discharge lamps. A DC voltage converter is often connected upstream of the inverter, which converter can perform power factor correction, for example. The DC voltage converter can be embodied as a boost, Sepic or flyback converter, for example. The DC voltage converter generates a regulated output voltage that is input into the inverter. This voltage is often referred to as the intermediate circuit voltage. The inverter can be embodied as a class E converter, as a half-bridge inverter or as a full-bridge inverter. The inverter correspondingly has between one and four metal oxide transistors. In such an operating device, said metal oxide transistors are often operated near the reverse voltage in continuous lamp operation. The lamp voltage of the gas discharge lamp to be operated is therefore in the region of the reverse voltage of the metal oxide transistor. In order that the electronic operating device can also be specified for outside applications at low ambient temperatures of e.g. −40° C. or alternatively applications in cold stores, which then entail a correspondingly low temperature of the circuit arrangement or of the metal oxide transistor, it is necessary to correspondingly preheat the metal oxide transistor or metal oxide transistors in order that they can block the lamp voltage of the gas discharge lamp that rises rapidly after the start. The time duration during which the metal oxide transistor is preheated, and during which the voltage applied to the transistor, e.g. the intermediate circuit voltage, is therefore reduced, is between 1 s and 120 s.

The metal oxide transistor can be heated by means of various methods. Many operating devices ignite the high pressure discharge lamps by means of resonance ignition, in a manner similar to the case for low pressure discharge lamps. During this resonance phase, a high current flows through the metal oxide transistor, which current can rapidly and reliably heat said transistor. In order to optimize the heating, the metal oxide transistor can be operated in the linear region during a short time period during the resonance ignition in order to accelerate the heat input into the transistor. This short time period, during which the metal oxide transistor has a higher forward resistance (R_{DSOn}), that is to say the resonance is damped meanwhile, is imperceptible to the user.

Another variant involves heating the metal oxide transistor during the heating phase of the high pressure discharge lamp. Shortly after ignition, a high pressure discharge lamp still has a very low lamp voltage, which rises continuously during the run-up of the lamp. The metal oxide transistor can likewise still be heated in this time, without running the risk of being destroyed by overvoltage. The heating is again effected by increased switching losses during the heating phase. The increased switching losses can arise e.g. as a result of capacitive operation of the metal oxide transistor, or as a result of an increase in the switching frequency, whereby the losses per unit time increase. The increase in the switching frequency affords the advantage that the voltage switched by the metal oxide transistor can thereby be reduced without extinction of the arc having to be feared. In the case of highly efficient converter strategies that have implemented zero voltage switching (ZVS) of the metal oxide transistor or zero current switching (ZCS) of the metal oxide transistor, there is the possibility of temporarily turning off this switching manifestation in order thus to generate increased switching losses and to rapidly heat the metal oxide transistor. Of course, here as well it is possible to drive the transistor in such a way that it operates in linear operation for a short time in order to further increase the switching losses and to further heat the transistor.

In a further embodiment, the two possibilities are combined, and the transistor is heated during the ignition of the high pressure discharge lamp and also during the run-up of the high pressure discharge lamp.

In the case of a circuit arrangement having a DC voltage converter, the intermediate circuit voltage can be reduced by the DC voltage converter during said run-up phase since, as already mentioned above, the lamp voltage is correspondingly low. This ensures that the metal oxide transistor can reliably block the voltage applied to it.

One possibility for controlling the heating phases is to measure the metal oxide transistor temperature. This can be done by a temperature sensor fitted to the metal oxide transistor or by means of the bulk resistance of the metal oxide transistor. The bulk resistance can be measured by means of a temperature-compensated measuring arrangement, and the chip temperature of the metal oxide transistor can thus be determined. The heating phases are then controlled until the transistor has reached a predetermined minimum temperature (e.g. +25° C.).

A simpler possibility consists in applying the heating phases of the metal oxide transistor to the latter in time-controlled fashion. This variant is simpler to realize, but has the disadvantage that the transistor is heated to an excessively great extent upon the start of a circuit that is already warm.

In specific applications and specific operating states (e.g. dimmed operation of a high pressure discharge lamp in a cold store), it can happen that the metal oxide transistor falls below a predetermined temperature. Additional heating phases then have to be provided in normal operation, too, in order to ensure reliable operation of the metal oxide transistor. The heating phases can be implemented into the operation of the high pressure discharge lamp according to the description above. In this context, linear operation of the metal oxide transistor and/or temporary switching off of the zero voltage switching (ZVS) of the metal oxide transistor or of the zero current switching (ZCS) of the metal oxide transistor are/is preferable to the other methods described.

1. A method for increasing the dielectric strength of at least one metal oxide transistor of an electronic circuit arrangement at low temperatures, the method comprising heating the metal oxide transistor prior to the application of a voltage in the vicinity of a breakdown voltage of the metal oxide transistor.

2. The method of claim 1, wherein the heating of the at least one metal oxide transistor comprises applying a high current through the at least one metal oxide transistor.

3. The method of claim 1, wherein the heating of the at least one metal oxide transistor comprises increasing switching losses of the at least one metal oxide transistor.

4. The method of claim 1, wherein the heating of the at least one metal oxide transistor comprises engaging the at least one metal oxide transistor in a momentary linear operation period.

5. The method of claim 1, wherein the method further comprises controlling the heating of the at least one metal oxide transistor in a time-controlled fashion.

6. The method of claim 1, wherein the method further comprises controlling the heating of the at least one metal oxide transistor in a temperature-controlled fashion.

7. The method of claim 1, wherein the method further comprises:
checking if a temperature of the circuit arrangement is low,
wherein heating the metal oxide transistor comprises if the temperature is low, heating the at least one metal oxide transistor prior to the application of a voltage in the vicinity of a breakdown voltage of the at least one metal oxide transistor.

8. The method of claim 7, wherein checking if the temperature of the circuit arrangement is low, comprises checking if the temperature of the circuit arrangement is below 25 degrees Celsius.

9. The method of claim 7, wherein checking if the temperature of the circuit arrangement is low, comprises checking if the temperature of the at least one metal oxide transistor is below 25 degrees Celsius.

10. A circuit arrangement having an increased dielectric strength at low temperatures, the circuit arrangement comprising at least one metal oxide transistor, wherein the circuit arrangement is configured to heat the at least one metal oxide transistor before the circuit arrangement applies to the at least one metal oxide transistor a voltage in the vicinity of the reverse voltage of the at least one metal oxide transistor.

11. The circuit arrangement of claim 10, wherein the circuit arrangement is configured to heat the at least one metal oxide transistor by applying a high current through the at least one metal oxide transistor.

12. The circuit arrangement of claim 10, wherein the circuit arrangement is configured to heat the at least one metal oxide transistor by increasing the switching losses of the at least one metal oxide transistor.

13. The circuit arrangement of claim 10, wherein the circuit arrangement is configured to heat the at least one metal oxide transistor by engaging the at least one metal oxide transistor in momentary linear operation period.

14. The circuit arrangement of claim 10, wherein the circuit arrangement is configured to control the heating of the at least one metal oxide transistor with time control.

15. The circuit arrangement of claim 10, wherein the circuit arrangement is configured to control the heating of the at least one metal oxide transistor with temperature control, wherein the circuit arrangement is configured to measure the temperature of the at least one metal oxide transistor.

16. The circuit arrangement of claim 15, wherein the circuit arrangement is configured to measure the temperature of the at least one metal oxide transistor by way of the channel resistance of the at least one metal oxide transistor.

17. The circuit arrangement of claim 15, wherein the circuit arrangement is configured to heat the at least one metal oxide transistor when the at least one metal oxide transistor is at low temperature.

18. The circuit arrangement of claim 17, wherein the circuit arrangement is configured to heat the at least one metal oxide transistor when the at least one metal oxide transistor is at a temperature below 25 degrees Celsius.

19. The circuit arrangement of claim 15, wherein the circuit arrangement is configured to heat the at least one metal oxide transistor when the circuit arrangement is at a low temperature.

20. The circuit arrangement of claim 19, wherein the circuit arrangement is configured to heat the at least one metal oxide transistor when the circuit arrangement is at a temperature below 25 degrees Celsius.

21. The circuit arrangement of claim 10, wherein the circuit arrangement is configured for operating at least one gas discharge lamp, wherein the circuit arrangement is further configured to:
generate an intermediate circuit voltage for application to the metal oxide transistor; and
heat the metal oxide transistor shortly before the start of the gas discharge lamp or upon the start of the gas discharge lamp.

22. The circuit arrangement of claim 21, wherein the circuit arrangement further comprises a DC voltage converter, the DC voltage converter comprising an adjustable output voltage for reducing the intermediate circuit voltage, wherein the output voltage of the DC voltage converter is the intermediate circuit voltage.

23. The circuit arrangement of claim 22, wherein the circuit arrangement is configured to reduce the intermediate circuit voltage during the heating phase, the heating phase comprising essentially a length of 1 second to 120 seconds.
